(19) United States
(12) Patent Application Publication
(10) Pub. No.: US 2026/0173625 A1
(43) Pub. Date: Jun. 18, 2026

(54) DISPLAY DEVICE

(71) Applicant: AUO Corporation, Hsinchu City (TW)

(72) Inventor: Fang-Cheng Yu, Hsinchu City (TW)

(73) Assignee: AUO Corporation, Hsinchu City (TW)

(21) Appl. No.: 19/227,393

(22) Filed: Jun. 3, 2025

(30) Foreign Application Priority Data
Dec. 12, 2024 (TW) 113148516

(51) Int. Cl. H10H 29/854; H01L 25/075; H10H 29/24; H10H 29/85; H10H 29/851

(52) U.S. Cl. CPC H10H 29/854; H10H 29/24; H10H 29/851; H10H 29/8517; H10W 90/00

(57) ABSTRACT

Provided is a display device, which includes a circuit substrate, a first light-emitting diode, a first padding layer, a second light-emitting diode, a color conversion layer, a first optical encapsulation layer, a bank, and an interface layer. The first light-emitting diode is disposed on the circuit substrate through a first electrode. The first padding layer is disposed on the circuit substrate. The second light-emitting diode is disposed on the first padding layer through a second electrode. The color conversion layer clads the first light-emitting diode. The first optical encapsulation layer clads the second light-emitting diode, and has a concave surface facing the second light-emitting diode. The bank is located on the circuit substrate and overlays a side surface of the color conversion layer, a side surface of the first optical encapsulation layer and a side surface of the first padding layer.

### CROSS-REFERENCE TO RELATED APPLICATION

This application claims the priority benefit of Taiwan application serial no. 113148516, filed on Dec. 12, 2024. The entirety of the above-mentioned patent application is hereby incorporated by reference herein and made a part of this specification.

### BACKGROUND

### Technical Field

The disclosure relates to a display device.

### Related Art

Currently, common micro light-emitting diode (μLED) color conversion architectures typically include elements such as a bank, a color conversion layer, and an optical encapsulation layer. The bank has a high optical density (OD) value, which may suppress the phenomenon of color conversion light cross talk in the color conversion architecture.

When there is a need to enhance resolution, a material of the bank is difficult to possess both a high optical density value and a high depth-to-width ratio at the same time. Therefore, the effect of enhancing resolution may be achieved by removing the bank from non-color conversion subpixels. However, the point light source characteristics of micro light-emitting diodes may be affected by a distance and optical characteristics of the bank, allowing light emission from non-color conversion subpixels to be asymmetrical, thereby having significant impact on the picture quality of the display device.

### SUMMARY

The disclosure provides a display device, which can maintain the picture quality of the display device while enhancing resolution.

The display device of the disclosure includes a circuit substrate, a first light-emitting diode, a first padding layer, a second light-emitting diode, a color conversion layer, a first optical encapsulation layer, a bank, and an interface layer. The first light-emitting diode is disposed on the circuit substrate through a first electrode. The first padding layer is disposed on the circuit substrate. The second light-emitting diode is disposed on the first padding layer through a second electrode. The color conversion layer clads the first light-emitting diode. The first optical encapsulation layer clads the second light-emitting diode. The first optical encapsulation layer has a concave surface facing the second light-emitting diode. The bank is located on the circuit substrate and overlays a side surface of the color conversion layer, a side surface of the first optical encapsulation layer, and a side surface of the first padding layer. The interface layer is located over the first optical encapsulation layer. There is a height difference between the first light-emitting diode and the second light-emitting diode.

Based on the above, the color conversion layer of the disclosure clads the first light-emitting diode. The second light-emitting diode is disposed on the first padding layer through the second electrode. The first optical encapsulation layer clads the second light-emitting diode. The first optical encapsulation layer has the concave surface facing the second light-emitting diode. The interface layer is located over the first optical encapsulation layer. In this way, the display device of the embodiment can allow a viewing angle distribution of non-color conversion subpixels to be similar to a viewing angle distribution of color conversion subpixels while enhancing resolution, maintaining the picture quality of the display device.

### BRIEF DESCRIPTION OF THE DRAWINGS

FIG. 1A is a schematic partial top view of a display device according to a first embodiment of the disclosure.

FIG. 1B is a schematic cross-sectional view of the display device along the sectional line A-A′ in FIG. 1A.

FIG. 2 is a diagram illustrating the relationship between a viewing angle and a ratio of light emission of the second light-emitting diode in FIG. 1B.

FIG. 3A is a schematic partial top view of a display device according to a second embodiment of the disclosure.

FIG. 3B is a schematic cross-sectional view of the display device along the sectional line B-B′ in FIG. 3A.

FIG. 4A is a schematic partial top view of a display device according to a third embodiment of the disclosure.

FIG. 4B is a schematic cross-sectional view of the display device along the sectional line C-C′ in FIG. 4A.

### DESCRIPTION OF THE EMBODIMENTS

As used herein, “about,” “approximately” or “substantially” includes the values as mentioned and the average values within the range of acceptable deviations that can be determined by those of ordinary skill in the art. Consider to the specific amount of errors related to the measurements (that is, the limitations of the measurement system), the meaning of “about” may be, for example, referred to a value within one or more standard deviations of the value, or within ±30%, ±20%, ±10%, ±5%. Furthermore, the “about,” “approximately” or “substantially” used herein may be based on the optical property, etching property or other properties to select a more acceptable deviation range or standard deviation, but may not apply one standard deviation to all properties.

In the drawings, the thickness of layers, films, panels, regions, etc., are exaggerated for clarity's sake. The same reference numerals refer to the same elements throughout the specification. It will be understood that when a component such as a layer, a film, a region, or a substrate is referred to be “on” or “connected to” another component, it may be directly on or connected to the other another component, or intermediate components may also exist there between. Comparatively, when a component is referred to be “directly on” or “directly connected” to another, none other intermediate component exits there between. As used herein, the “connection” may refer to physical and/or electrical connection. Furthermore, “electrical connection” of two components may refer to that other components may exist between the two components.

Moreover, relative terms such as “under” or “bottom” and “above” or “top” may be used for describing a relationship of one element and another element as that shown in figures. It should be noted that the relative terms are intended to include a different orientation of the device besides the orientation shown in the figure. For example, if a device in a figure is flipped over, the element originally described to be located “under” other element is oriented to be located “above” the other element. Therefore, the illustrative term “under” may include orientations of “under” and “on”, which is determined by the specific orientation of the figure. Similarly, if a device in a figure is flipped over, the element originally described to be located “below” or “underneath” other element is oriented to be located “on” the other element. Therefore, the illustrative term “under” or “below” may include orientations of “above” and “under”.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The exemplary embodiment is described below with reference of a cross-sectional view of a schematic diagram of an idealized embodiment. Therefore, a shape change of the figure serving as a result of manufacturing techniques and/or tolerances may be expected. Therefore, the embodiment of the disclosure should not be construed as limited to a particular shape of a region as shown herein, but includes a shape deviation caused by manufacturing tolerance. For example, a shown or described flat area may generally have rough and/or non-linear features. Moreover, a shown acute angle may be round. Therefore, a region shown in the figure is essentially schematic, and a shape thereof is not intended to show an accurate shape of the region, and is not intended to limit a range of the claims of the disclosure.

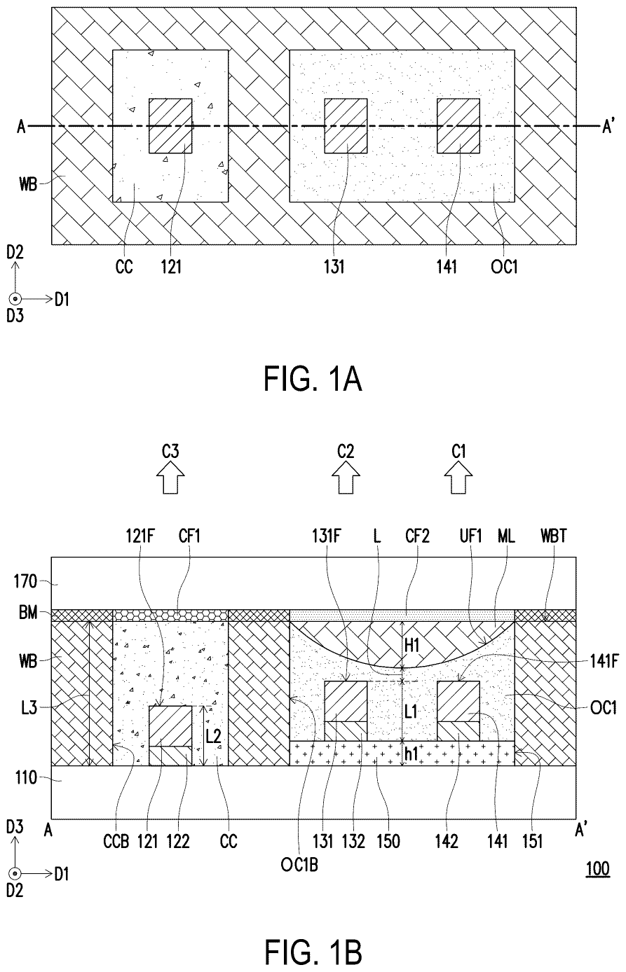

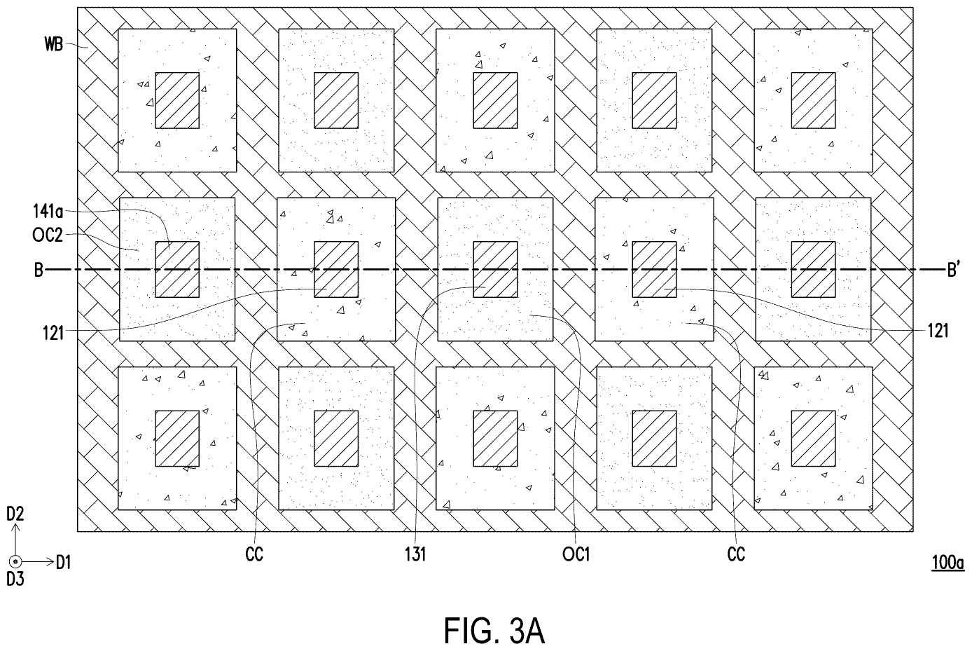

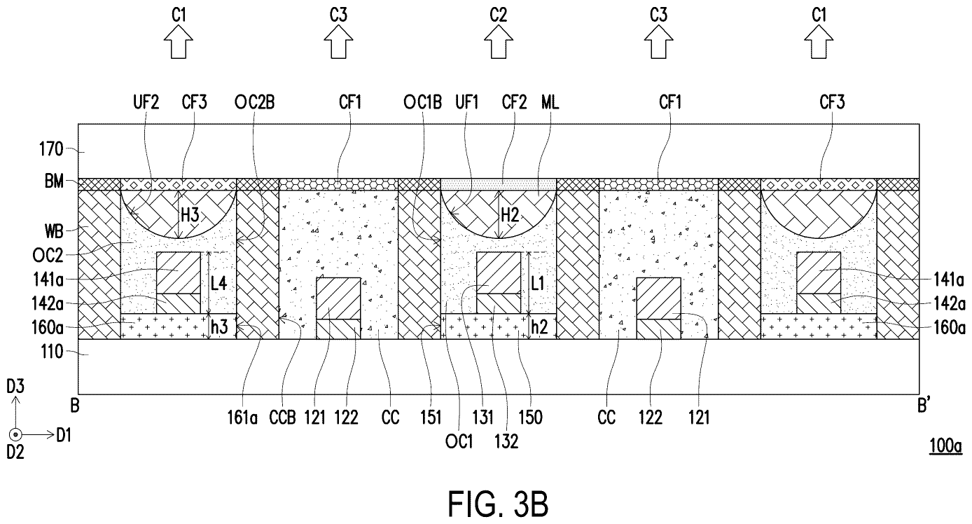

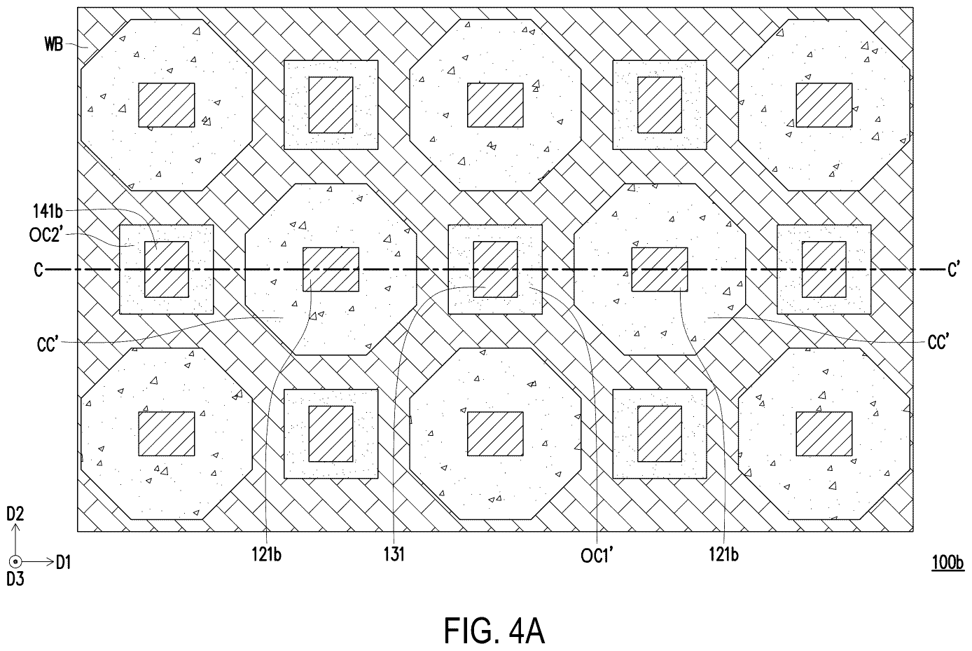

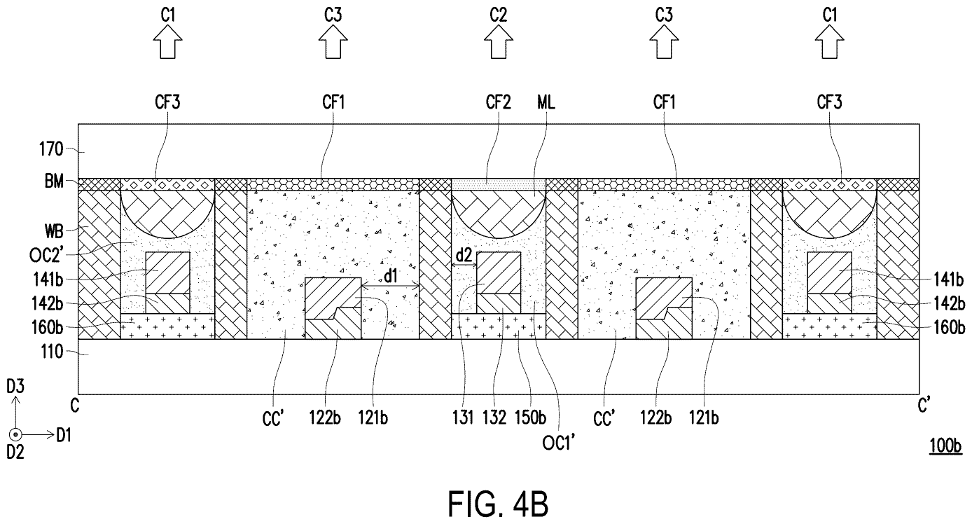

For convenience of description, only several first light-emitting diodes 121 and 121b, second light-emitting diodes 131, and third light-emitting diodes 141, 141a, and 141b are illustrated in each figure, but an actual quantity may be more and is not limited thereto. Furthermore, display devices 100, 100a, and 100b may be a device arranged in an array according to an order of the first light-emitting diodes 121 and 121b, the second light-emitting diodes 131, and the third light-emitting diodes 141, 141a, and 141b as shown in each figure. In addition, to clearly see the arrangement manner of the elements, FIG. 1A, FIG. 3A and FIG. 4A omit a glass substrate 170, a light shielding layer BM, an interface layer ML, and color filter layers CF1, CF2, and CF3.

FIG. 1A is a schematic partial top view of a display device according to a first embodiment of the disclosure. FIG. 1B is a schematic cross-sectional view of the display device along the sectional line A-A′ in FIG. 1A. Please refer to FIG. 1A and FIG. 1B. The display device 100 includes a circuit substrate 110, the first light-emitting diode 121, a color conversion layer CC, and a bank WB. The first light-emitting diode 121 is disposed over the circuit substrate 110 through a first electrode 122. The color conversion layer CC is disposed over the circuit substrate 110 and clads the first light-emitting diode 121 and the first electrode 122. The bank WB is located on the circuit substrate 110 and overlays a side surface CCB of the color conversion layer CC. The first light-emitting diode 121, the first electrode 122, and the color conversion layer CC form, for example, a color conversion subpixel.

Specifically, the first light-emitting diode 121 is, for example, a micro light-emitting diode. The first light-emitting diode 121 may emit light of a first color C1 which is, for example, blue. However, the disclosure is not limited thereto. The color conversion layer CC may include phosphor, quantum dots (QD), or wavelength conversion materials with similar properties, such as silicate, silicon nitride, sulfide, quantum dot type, or garnet type wavelength conversion materials to allow light emitted by the first light-emitting diode 121 to be converted to light of a needed color. For example, in the embodiment, the color conversion layer CC may be the photoresistive color conversion layer CC and may respectively include a photoresist matrix and phosphors including different activators. The activators in the phosphor may be excited by an energy from light of the first color C1 (such as blue) from the first light-emitting diode 121 to be released and converted to light of a third color C3 (such as red).

The bank WB may include an organic material (such as photoresist) and a reflective material disposed on a surface or inside the organic material. The bank WB may also include, for example, silicon dioxide, optical adhesive, or other suitable materials. The disclosure is not limited thereto. Furthermore, a height L3 of the bank WB is between 1.5 times and 3 times a height L2 of the first light-emitting diode 121 and the first electrode 122. The height L3 of the bank WB is, for example, approximately 20 microns to 22 microns. The height L2 of the first light-emitting diode 121 and the first electrode 122 is, for example, approximately 9 microns to 10 microns.

When light emitted by the first light-emitting diode 121 directly passes through the color conversion layer CC, the light emitted by the first light-emitting diode 121 may not be completely converted to light of the third color C3. When the height L3 of the bank WB is between the foregoing values, the bank WB overlaying the side surface CCB of the color conversion layer CC may reflect the light emitted by the first light-emitting diode 121 back to the color conversion layer CC to effectively enhance the light conversion efficiency, and may suppress the light cross-talk phenomenon. The bank WB may also enhance the light emission efficiency at a normal viewing angle to prevent light from being emitted from various angles, causing light emission to be dispersed, and reducing the brightness at the normal viewing angle.

The display device 100 of the embodiment further includes the second light-emitting diode 131, the third light-emitting diode 141, a first padding layer 150, and a first optical encapsulation layer OC1. The first padding layer 150 is disposed on the circuit substrate 110 and has a spacing from the color conversion layer CC through the bank WB in a first direction D1. The second light-emitting diode 131 is disposed on the first padding layer 150 through a second electrode 132. The third light-emitting diode 141 is disposed on the first padding layer 150 through a third electrode 142. The first optical encapsulation layer OC1 is disposed over the first padding layer 150 and clads the second light-emitting diode 131, the second electrode 132, the third light-emitting diode 141, and the third electrode 142 at the same time. The bank WB overlays a side surface OC1B of the first optical encapsulation layer OC1 and a side surface 151 of the first padding layer 150. The second light-emitting diode 131, the second electrode 132, the third light-emitting diode 141, the third electrode 142, the first padding layer 150, and the first optical encapsulation layer OC1 form, for example, a non-color conversion subpixel.

Specifically, the second light-emitting diode 131 and the third light-emitting diode 141 are elements with similar structures to the first light-emitting diode 121 and are, for example, all micro light-emitting diodes. The second light-emitting diode 131 may emit light of a second color C2 which is, for example, green. The third light-emitting diode 141 may emit light of the first color C1 which is, for example, blue. However, the disclosure is not limited thereto. The first padding layer 150 is, for example, transparent, graphical, and a photoresist made of an organic material. The first optical encapsulation layer OC1 is, for example, a transparent encapsulation adhesive layer. However, the disclosure is not limited thereto. Light of the second color C2 and light of the first color C1 respectively emitted by the second light-emitting diode 131 and the third light-emitting diode 141 may be emitted upward (that is, a third direction D3) through the first optical encapsulation layer OC1.

It should be specifically noted that the first light-emitting diode 121 is disposed on the circuit substrate 110 through the first electrode 122. The second light-emitting diode 131 is disposed on the circuit substrate 110 through the second electrode 132 and the first padding layer 150. The third light-emitting diode 141 is disposed on the circuit substrate 110 through the third electrode 142 and the first padding layer 150. In other words, there is a height difference between the first light-emitting diode 121 and the second light-emitting diode 131, and between the first light-emitting diode 121 and the third light-emitting diode 141. The height difference is a thickness h1 of the first padding layer 150. A light-emitting surface 131F of the second light-emitting diode 131 and a light-emitting surface 141F of the third light-emitting diode 141 are closer to a top surface WBT of the bank WB compared to a light-emitting surface 121F of the first light-emitting diode 121. Through the foregoing design, a light emission angle of a point light source of the second light-emitting diode 131 and the third light-emitting diode 141 may be expanded, allowing viewing angles of the second light-emitting diode 131 and the third light-emitting diode 141 to be more symmetrical to reduce the problem of asymmetrical viewing angles of non-color conversion subpixels.

The display device 100 of the embodiment further includes the interface layer ML. The interface layer ML is located over the first optical encapsulation layer OC1. In addition, the first optical encapsulation layer OC1 has a concave surface UF1 (that is, concave in an opposite direction of the third direction D3) facing the second light-emitting diode 131. The interface layer ML is connected to the concave surface UF1 of the first optical encapsulation layer OC1. A distance L in a vertical direction (that is, the distance L in the third direction D3) between the concave surface UF1 and the light-emitting surface 131F of the second light-emitting diode 131 is between 0.5 microns and 1 micron.

Furthermore, a refractive index of the interface layer ML is less than a refractive index of the first optical encapsulation layer OC1. The refractive index of the interface layer ML is between 0.9 and 1.3. The interface layer ML may be, for example, air. However, the disclosure is not limited thereto. The refractive index of the first optical encapsulation layer OC1 is between 1.4 and 1.8.

When the point light source of the second light-emitting diode 131 and the point light source of the third light-emitting diode 141 transmit to the interface layer ML from the first optical encapsulation layer OC1, the point light source of the second light-emitting diode 131 and the point light source of the third light-emitting diode 141 may deviate from a normal line and form scattering due to the design of different refractive indices between the interface layer ML and the first optical encapsulation layer OC1. The foregoing point light sources may also increase a scattering angle as a concave depth H1 of the concave surface UF1 increases. That is to say, through the design of the concave surface UF1 and different refractive indices, the scattering angles of the point light source of the second light-emitting diode 131 and the point light source of the third light-emitting diode 141 may be increased, further reducing the problem of asymmetrical viewing angles of non-color conversion subpixels.

In addition, a total value of the depth H1 of the concave surface UF1 and the thickness h1 of the first padding layer 150 is between ⅔ times and 4/3 times a height L1 of the second light-emitting diode 131 and the second electrode 132. The height L1 of the second light-emitting diode 131 is, for example, approximately 9 microns to 10 microns. When the total value of the depth H1 of the concave surface UF1 and the thickness h1 of the first padding layer 150 is within the foregoing range, viewing angles of non-color conversion subpixels may be more symmetrical, allowing a viewing angle distribution of non-color conversion subpixels to be similar to a viewing angle distribution of color conversion subpixels. In other words, through combining the first padding layer 150 with the concave surface UF1 and the design of different refractive indices, a process height difference of the display device 100 may be reduced, and the point light source of the second light-emitting diode 131 and the point light source of the third light-emitting diode 141 may have a good level of scattering, thereby eliminating the problem of asymmetrical viewing angles due to asymmetrical distances between the second light-emitting diode 131 and the bank WB, and between the third light-emitting diode 141 and the bank WB.

It should be added that if only the first padding layer 150 is added to the display device 100, or if only the concave surface UF1 combined with the design of different refractive indices is added to the display device 100, the difficulty in the manufacturing process may be increased.

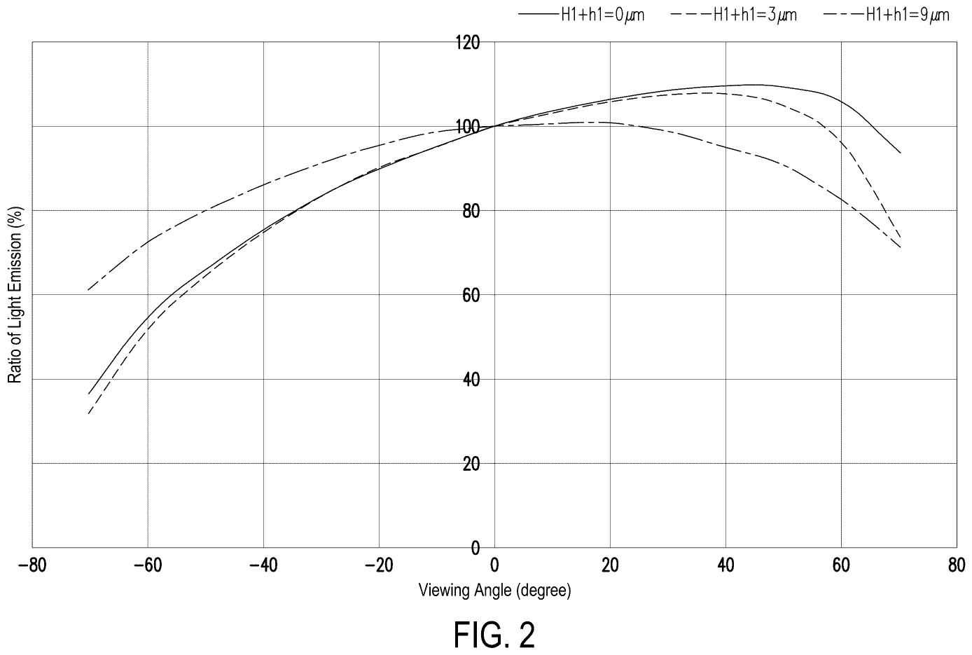

FIG. 2 is a diagram illustrating the relationship between a viewing angle and a ratio of light emission of the second light-emitting diode in FIG. 1. Please refer to FIG. 2. Taking the second light-emitting diode 131 as an example, in a condition without the first padding layer 150, the concave surface UF1, and the refractive index difference design (that is, a condition where H1+h1=0 μm), the ratio of light emission of the point light source of the second light-emitting diode 131 at various viewing angles is not symmetrical. In a condition with the first padding layer 150, the concave surface UF1, and the refractive index difference design (that is, conditions where H1+h1=3μm and H1+h1=9 μm), the ratio of light emission of the point light source of the second light-emitting diode 131 at various viewing angles is more symmetrical. In addition, when the total value of the depth H1 of the concave surface UF1 and the thickness h1 of the first padding layer 150 is between ⅔ times to 4/3 times the height L1 of the second light-emitting diode 131 and the second electrode 132 (that is, the condition where H1+h1=9 μm), the ratio of light emission of the point light source of the second light-emitting diode 131 at various viewing angles is even more symmetrical. That is to say, the design of the first padding layer 150 combined with the concave surface UF1 and the refractive index difference may effectively improve the foregoing problem of viewing angle asymmetry, thereby enhancing the picture quality of the display device 100.

Based on the above, the color conversion layer CC clads the first light-emitting diode 121. The second light-emitting diode 131 and the third light-emitting diode 141 are disposed on the first padding layer 150 respectively through the second electrode 132 and the third electrode 142. The first optical encapsulation layer OC1 clads the second light-emitting diode 131, the second electrode 132, the third light-emitting diode 141, and the third electrode 142. The first optical encapsulation layer OC1 has the concave surface UF1. The interface layer ML is located over the first optical encapsulation layer OC1. The refractive index of the interface layer ML is less than the refractive index of the first optical encapsulation layer OC1. The total value of the depth H1 of the concave surface UF1 and the thickness h1 of the first padding layer 150 is between ⅔ times to 4/3 times the height L1 of the second light-emitting diode 131 and the second electrode 132. In this way, the display device 100 of the embodiment may allow the viewing angle distribution of non-color conversion subpixels to be similar to the viewing angle distribution of color conversion subpixels while enhancing resolution, maintaining the picture quality of the display device 100.

The display device 100 of the embodiment further includes the color filter layers CF1 and CF2, the light shielding layer BM, and the glass substrate 170. The color filter layers CF1 and CF2 are located in a same layer with the light shielding layer BM. The light shielding layer BM is located between the color filter layers CF1 and CF2. The color filter layer CF1 is located between the glass substrate 170 and the color conversion layer CC. The color filter layer CF2 is located between the glass substrate 170 and the interface layer ML. The light shielding layer BM is located between the glass substrate 170 and the bank WB. The light shielding layer BM may be configured to define a formation location of the color filter layers CF1 and CF2. For example, the light shielding layer BM may have an opening, and the color filter layers CF1 and CF2 are located in the opening to improve the overall color contrast.

As shown in FIG. 1B, the color filter layer CF1 is located over the color conversion layer CC and is disposed corresponding to the first light-emitting diode 121. The color filter layer CF2 is located over the first optical encapsulation layer OC1 and is disposed corresponding to the second light-emitting diode 131 and the third light-emitting diode 141. The color filter layer CF1 may, for example, allow light of the third color C3 (such as red) to pass through and allow light of other colors to be blocked and filtered. The color filter layer CF2 may, for example, allow light of the first color C1 (such as blue) and the second color C2 (such as green) to pass through and allow light of other colors to be blocked and filtered.

In addition, a material of the light shielding layer BM may include black resin, black chromium materials (CrOx/CrNx/Cr) or other materials that are not easily reflective, or other suitable materials or a combination of the foregoing materials. However, the disclosure is not limited thereto.

It must be noted here that the following embodiments use the reference numerals and part of the contents of the foregoing embodiments. The same numerals are used to denote the same or similar elements, and the description of the same technical content is omitted. For the description of the omitted parts, reference may be made to the foregoing embodiments, and thus the description is not repeated in the following embodiments.

FIG. 3A is a schematic partial top view of a display device according to a second embodiment of the disclosure. FIG. 3B is a schematic cross-sectional view of the display device along the sectional line B-B′ in FIG. 3A. Please refer to FIG. 3A and FIG. 3B. The main difference between the display device 100a of the embodiment and the display device 100 is that an arrangement location of a third light-emitting diode 141a is different from an arrangement location of the third light-emitting diode 141, and a distance of the bank WB is reduced to enhance resolution.

In detail, the display device 100a includes a second padding layer 160a and a second optical encapsulation layer OC2. The second padding layer 160a is disposed on the circuit substrate 110 and has a spacing from the color conversion layer CC through the bank WB in the first direction D1. The third light-emitting diode 141a is disposed on the second padding layer 160a through a third electrode 142a. The first light-emitting diode 121 is located between the second light-emitting diode 131 and the third light-emitting diode 141a in the first direction D1. There is a height difference between the first light-emitting diode 121 and the third light-emitting diode 141a. The height difference is a thickness h3 of the second padding layer 160a.

The first optical encapsulation layer OC1 is disposed on the first padding layer 150 and clads the second light-emitting diode 131 and the second electrode 132, and, for example, forms a non-color conversion subpixel. The first optical encapsulation layer OC1 has the concave surface UF1 facing the second light-emitting diode 131. The second optical encapsulation layer OC2 is disposed over the second padding layer 160a and clads the third light-emitting diode 141a and the third electrode 142a, and, for example, forms another non-color conversion subpixel. The second optical encapsulation layer OC2 also has another concave surface UF2 facing the third light-emitting diode 141a. The second optical encapsulation layer OC2 may utilize a same material as the first optical encapsulation layer OC1, allowing a refractive index of the interface layer ML to be less than a refractive index of the second optical encapsulation layer OC2.

Similarly, the bank WB overlays a side surface OC2B of the second optical encapsulation layer OC2 and a side surface 161a of the second padding layer 160a. The interface layer ML is on the second optical encapsulation layer OC2. The color filter layer CF3 is located between the glass substrate 170 and the interface layer ML. The color filter layer CF3 is disposed on the second optical encapsulation layer OC2 corresponding to the third light-emitting diode 141a. In the embodiment, the color filter layer CF2 may, for example, allow light of the second color C2 (such as green) to pass through and allow light of other colors to be blocked and filtered. The color filter layer CF3 may, for example, allow light of the first color C1 (such as blue) to pass through and allow light of other colors to be blocked and filtered.

As shown in FIG. 3A and FIG. 3B, in a direction from left to right (that is, the first direction D1), the third light-emitting component 141a, the first light-emitting component 121, the second light-emitting component 131, and the other first light-emitting component 121 are arranged in sequence. Light emitted by these elements after passing through the color filter layers CF1, CF2, and CF3 is for example, arranged in an order of light emission colors of the first color C1, the third color C3, the second color C2, and the third color C3 (that is, for example, in an order of blue light, red light, green light, and red light). In addition, in a direction from bottom to top (that is, the second direction D2 in FIG. 3A), the light is also, for example, arranged in the foregoing order of light emission colors. Through the subpixel rendering configuration, a quantity of banks may be reduced, and a pixel density of the display device 100a may be increased.

In addition, a total value of a depth H2 of the concave surface UF1 and a thickness h2 of the first padding layer 150 in the embodiment is between ⅔ times to 3/2 times of the height L1 of the second light-emitting diode 131 and the second electrode 132. A total value of a depth H3 of another concave surface UF2 and a thickness h3 of the second padding layer 160 a is between ⅔ times to 3/2 times of a height L4 of the third light-emitting diode 141 a and the third electrode 142 a. The height L1 and the height L4 are, for example, approximately 9 microns to 10 microns. It should be added that, since the second light-emitting diode 131 and the second electrode 132, and the third light-emitting diode 141a and the third electrode 142a are similar elements, the height L1 and the height L4 are actually similar values. In addition, since a distance of the bank WB is reduced in the embodiment, in a condition where a sum of the depths H2 and H3, and the thicknesses h2 and h3 is greater, the problem of viewing angle narrowing effect can be better eliminated.

The display device 100a of the embodiment may also, through the design of having the first padding layer 150, the concave surface UF1, the second padding layer 160a, the other concave surface UF2, and different refractive indices, allow the point light source of the second light-emitting diode 131 and the point light source of the third light-emitting diode 141a to have a good level of scattering, reduce the viewing angle narrowing effect caused by the nearby bank WB, and enhance the viewing angle symmetry of non-color conversion subpixels and color conversion subpixels.

FIG. 4A is a schematic partial top view of a display device according to a third embodiment of the disclosure. FIG. 4B is a schematic cross-sectional view of the display device along the sectional line C-C′ in FIG. 4A. Please refer to FIG. 4A and FIG. 4B. A relationship of relative locations of the elements in the embodiment, such as a first light-emitting diode 121b, a first electrode 122b, the second light-emitting diode 131, the second electrode 132, a third light-emitting diode 141b, a third electrode 142b, a first padding layer 150b, a second padding layer 160b, the bank WB, a first optical encapsulation layer OC1', a second optical encapsulation layer OC2', a color conversion layer CC′ are all the same as a relationship of relative locations of the corresponding elements in the second embodiment, so descriptions of the same technical content is omitted below.

Since a structure of the display device 100b in the embodiment is similar to a structure of the display device 100a, the display device 100b may also, through the design of having the first padding layer 150b, the concave surface UF1, the second padding layer 160b, the other concave surface UF2, and different refractive indices, reduce the viewing angle narrowing effect caused by the nearby bank WB, and enhance the viewing angle symmetry of non-color conversion subpixels and color conversion subpixels.

The main difference between the display device 100b and the display device 100a is that an area of the color conversion layer CC′ in the display device 100b is expanded, areas of the first optical encapsulation layer OC1′ and the second optical encapsulation layer OC2′ are shrunk, and orientation locations of the first light-emitting diode 121b and the first electrode 122b are turned.

In detail, a distance d1 between the first light-emitting diode 121b and the bank WB in the embodiment is greater than a distance d2 between the second light-emitting diode 131 and the bank WB. The distance d1 between the first light-emitting diode 121b and the bank WB is, for example, between 1.5 times and 3 times the distance d2 between the second light-emitting diode 131 and the bank WB. In other words, as shown in FIG. 4A, the area of the color conversion layer CC′ is greater than the area of the first optical encapsulation layer OC1′ and the area of the second optical encapsulation layer OC2'. Generally, the color conversion layer CC′ (such as the color conversion layer CC′ that converts light to red) needs higher brightness, and a light-emitting area is proportional to the brightness. Therefore, through the arrangement of increasing the area of the color conversion layer CC′ in the embodiment, the display device 100b may enhance brightness in a condition of high resolution.

It should be added that if the distance d1 between the first light-emitting diode 121b and the bank WB is too long, light from the first light-emitting diode 121b passing through the color conversion layer CC′ may be weakened, which may instead fail to enhance brightness.

In addition, an arrangement direction of the first light-emitting diode 121b in the embodiment is different from an arrangement direction of the second light-emitting diode 131 and the third light-emitting diode 141b. Specifically, the arrangement direction of the first light-emitting diode 121b is, for example, facing the first direction D1 in a horizontal direction. The arrangement direction of the second light-emitting diode 131 and the third light-emitting diode 141b is, for example, facing the second direction D2 perpendicular to the first direction D1. Through such arrangement, the light emission brightness in the horizontal direction (that is, the first direction D1) can be further enhanced.

In summary, the color conversion layer of the disclosure clads the first light-emitting diode. The second light-emitting diode is disposed on the first padding layer through the second electrode. The first optical encapsulation layer clads the second light-emitting diode. The first optical encapsulation layer has the concave surface facing the second light-emitting diode. The interface layer is located over the first optical encapsulation layer. In this way, the display device of the embodiment can allow the viewing angle distribution of non-color conversion subpixels to be similar to the viewing angle distribution of color conversion subpixels while enhancing resolution, maintaining the picture quality of the display device.

What is claimed is:

1. A display device, comprising:
a circuit substrate;
a first light-emitting diode, disposed on the circuit substrate through a first electrode;
a first padding layer, disposed on the circuit substrate;
a second light-emitting diode, disposed on the first padding layer through a second electrode;
a color conversion layer, cladding the first light-emitting diode;
a first optical encapsulation layer, cladding the second light-emitting diode, wherein the first optical encapsulation layer has a concave surface facing the second light-emitting diode;
a bank, located on the circuit substrate and overlaying a side surface of the color conversion layer, a side surface of the first optical encapsulation layer, and a side surface of the first padding layer; and
an interface layer, located over the first optical encapsulation layer, wherein
there is a height difference between the first light-emitting diode and the second light-emitting diode.

2. The display device according to claim 1, wherein a refractive index of the interface layer is less than a refractive index of the first optical encapsulation layer.

3. The display device according to claim 2, wherein the refractive index of the first optical encapsulation layer is between 1.4 and 1.8, and the refractive index of the interface layer is between 0.9 and 1.3.

4. The display device according to claim 1, further comprising a third light-emitting diode disposed on the first padding layer, wherein the first optical encapsulation layer clads the second light-emitting diode and the third light-emitting diode at a same time.

5. The display device according to claim 4, wherein a total value of a depth of the concave surface and a thickness of the first padding layer is between ⅔ times and 4/3 times a height of the second light-emitting diode and the second electrode.

6. The display device according to claim 1, further comprising:
a second padding layer, disposed on the circuit substrate;
a third light-emitting diode, disposed on the second padding layer through a third electrode, wherein the first light-emitting diode is located between the second light-emitting diode and the third light-emitting diode; and
a second optical encapsulation layer, cladding the third light-emitting diode, wherein the second optical encapsulation layer has another concave surface facing the third light-emitting diode, wherein
the bank overlays a side surface of the second optical encapsulation layer, the interface layer is located on the second optical encapsulation layer, and there is a height difference between the first light-emitting diode and the third light-emitting diode.

7. The display device according to claim 6, wherein an arrangement direction of the first light-emitting diode is different from an arrangement direction of the second light-emitting diode.

8. The display device according to claim 6, wherein a distance between the first light-emitting diode and the bank is greater than a distance between the second light-emitting diode and the bank.

9. The display device according to claim 6, wherein a total value of a depth of the concave surface and a thickness of the first padding layer is between ⅔ times and 3/2 times a height of the second light-emitting diode and the second electrode, and a total value of a depth of the other concave surface and a thickness of the second padding layer is between ⅔ times and 3/2 times a height of the third light-emitting diode and the third electrode.

10. The display device according to claim 1, further comprising a color filter layer and a glass substrate, wherein the color filter layer is located between the glass substrate and the interface layer.

11. A display device, comprising:
a circuit substrate;
a first light-emitting diode, disposed on the circuit substrate through a first electrode;
a first padding layer, disposed on the circuit substrate;
a second light-emitting diode, disposed on the first padding layer through a second electrode;
a color conversion layer, cladding the first light-emitting diode;
a color filter layer, wherein the color conversion layer is disposed between the color filter layer and the first light-emitting diode;
a first optical encapsulation layer, cladding the second light-emitting diode, wherein the first optical encapsulation layer has a concave surface facing the second light-emitting diode;
a bank, located on the circuit substrate and overlaying a side surface of the color conversion layer, a side surface of the first optical encapsulation layer and a side surface of the first padding layer; and
an interface layer, located over the first optical encapsulation layer, wherein
there is a height difference between the first light-emitting diode and the second light-emitting diode.

12. The display device according to claim 11, wherein a refractive index of the interface layer is less than a refractive index of the first optical encapsulation layer.

13. The display device according to claim 11, further comprising a third light-emitting diode disposed on the first padding layer, wherein the first optical encapsulation layer clads the second light-emitting diode and the third light-emitting diode at a same time.

14. The display device according to claim 13, wherein a total value of a depth of the concave surface and a thickness of the first padding layer is between ⅔ times and 4/3 times a height of the second light-emitting diode and the second electrode.

15. The display device according to claim 11, further comprising:
a second padding layer, disposed on the circuit substrate;
a third light-emitting diode, disposed on the second padding layer through a third electrode, wherein the first light-emitting diode is located between the second light-emitting diode and the third light-emitting diode; and
a second optical encapsulation layer, cladding the third light-emitting diode, wherein the second optical encapsulation layer has another concave surface facing the third light-emitting diode, wherein
the bank overlays a side surface of the second optical encapsulation layer, the interface layer is located on the second optical encapsulation layer, and there is a height difference between the first light-emitting diode and the third light-emitting diode.

16. The display device according to claim 15, wherein an arrangement direction of the first light-emitting diode is different from an arrangement direction of the second light-emitting diode.

17. The display device according to claim 15, wherein a distance between the first light-emitting diode and the bank is greater than a distance between the second light-emitting diode and the bank.

18. The display device according to claim 15, wherein a total value of a depth of the concave surface and a thickness of the first padding layer is between ⅔ times and 3/2 times a height of the second light-emitting diode and the second electrode, and a total value of a depth of the other concave surface and a thickness of the second padding layer is between ⅔ times and 3/2 times a height of the third light-emitting diode and the third electrode.
